(19) United States
(12) Patent Application Publication
(10) Pub. No.: US 2023/0163193 A1
(43) Pub. Date: May 25, 2023

(54) Heterojunction Bipolar Transistor and Method of Manufacturing the Same

(71) Applicant: Nippon Telegraph and Telephone Corporation, Tokyo (JP)

(72) Inventors: Yuta Shiratori, Tokyo (JP); Takuya Hoshi, Tokyo (JP)

(21) Appl. No.: 17/915,018

(22) PCT Filed: Apr. 21, 2020
(86) PCT No.: PCT/JP2020/017177

§ 371 Date: Sep. 27, 2022

(51) Int. Cl. H01L 29/66; H01L 29/737; H01L 29/205

(52) U.S. Cl. CPC H01L 29/66318; H01L 29/737; H01L 29/205

(57) ABSTRACT

A heterojunction bipolar transistor includes a first emitter electrode, a second emitter electrode, and a third emitter electrode that are formed on an emitter cap layer. The first emitter electrode has an area greater than or equal to an area of the emitter cap layer in a plan view, and is made of a tungsten alloy. The second emitter electrode is formed on the first emitter electrode, is made of a metal that contains W and is different from a metal of the first emitter electrode, and has an area greater than an area of the first emitter electrode in a plan view.

### CROSS-REFERENCE TO RELATED APPLICATIONS

This patent application is a national phase filing under section 371 of PCT application no. PCT/JP2020/017177, filed on Apr. 21, 2020, which is incorporated herein by reference in its entirety.

### TECHNICAL FIELD

The present disclosure relates to a heterojunction bipolar transistor and a method of manufacturing the heterojunction bipolar transistor.

### BACKGROUND

A heterojunction bipolar transistor (HBT) made of an indium phosphide (InP)-based material has excellent high speed and high power characteristics, and is particularly applied to a front end integrated circuit (IC) of a high-volume optical communication in which very high frequency operation is required. As a request for an application, it is further required to enhance the speed of the HBT.

In the high frequency characteristics of the HBT, in order to improve particularly a maximum oscillation frequency required in the above application, it is effective to reduce an intrinsic collector capacitance by downsizing an emitter and also reduce base resistance. The base resistance is a sum of intrinsic base resistance generated in a base layer immediately below an emitter layer, base access resistance generated in the base layer from an emitter end to a base electrode end, and base electrode resistance generated in a base electrode. Reduction of an emitter width is important for reduction of the intrinsic base resistance. Reduction of the spacing between the emitter and the base electrode is important for reduction of the base access resistance. Thickening of the base electrode is important for reduction of the base electrode resistance.

However, there is a limitation to achieving the three dimensional improvements described above in the related art without trade-offs. FIG. 3 illustrates an example of an InP-based HBT. The HBT includes, on or over a substrate 301 made of InP doped with Fe to have high resistance, a sub-collector layer 302 made of InGaAs/InP doped with an n-type impurity at a high concentration, a collector layer 303 made of InP doped with an n-type impurity, a base layer 304 made of InGaAsSb doped with a p-type impurity at a high concentration, and an emitter layer 305 made of InP doped with an n-type impurity. An emitter cap layer 306 made of InGaAs doped with an n-type impurity at a high concentration is formed on the emitter layer 305.

A collector electrode 311 is formed on the sub-collector layer 302 around the collector layer 303, and a base electrode 312 is formed on the base layer 304 around the emitter layer 305. The base electrode 312 is formed while surrounding the outer circumference of the emitter layer 305 to decrease the base resistance. A first emitter electrode 313 is formed on the emitter cap layer 306, and a second emitter electrode 314 is formed on the first emitter electrode 313. A protective film 307 made of an insulating material is formed covering a side face of the emitter cap layer 306.

In the method for manufacturing the HBT configured as described above, a resist pattern that is open in a range from one end to the other end of the base layer is formed with an emitter interposed therein in a plan view, and in this state, a base electrode metal is deposited and unnecessary metal on the resist pattern is removed, whereby the base electrode is formed. In the manufacturing process, the metal serving as the base electrode is deposited collectively over the forming region of the emitter electrode in addition to the forming region of the base electrode.

According to this forming method, an undercut structure is previously provided between the emitter electrode and the emitter cap layer in a sectional view, and thus the emitter electrode serves as an overhang, which enables the base electrode to be formed as close to the emitter as possible while the electrical short-circuit between the emitter and the base electrode is avoided. In principle, the spacing between the emitter layer and the base electrode can be reduced to a distance corresponding to the undercut amount in the emitter cap layer, and a value of about 0.05 μm has been reported as this spacing (NPL 1).

In this structure, in principle, when the InGaAs emitter cap layer is formed thicker, the base electrode also can be formed thicker without short-circuiting between the emitter electrode and the base electrode, and the resistance of the base electrode can also be decreased.

### CITATION LIST

### Non Patent Literature

NPL 1: N. Kashio et al., “Composition- and Doping-Graded-Base InP/InGaAsSb Double Heterojunction Bipolar Transistors Exhibiting Simultaneous ft and fmax of Over 500 GHz” IEEE ELECTRON DEVICE LETRS, vol. 35, no. 12, pp. 1209-1211, 2014.

### SUMMARY

### Technical Problem

However, in the HBT described above, it is practically very difficult to control the undercut amount of the emitter cap layer and the tapered shape of the emitter cap layer in a sectional view. There is also a trade-off between the thickness of the base electrode and the spacing between the emitter layer and the base electrode. For these reasons, in the related-art HBT, it is difficult to further improve the high-frequency characteristics.

First, in the process of forming the emitter cap layer, both dimensional control and selectivity of not etching the underlying emitter layer are required to be achieved. Because of this, a process is typically used in which a certain thickness is etched by a dry etch method achieving high verticality, and then the remaining emitter cap layer is completely removed by wet etching in consideration of selectivity between the emitter cap layer and the emitter layer. In this method, a material specific crystal surface in which wet etching hardly advances in principle is formed. For example, when InGaAs is etched using a citric acid-based etchant, a section (FIG. 3) perpendicular to the <011> direction has a so-called reverse tapered structure in which a width of the emitter cap layer narrows from a part in contact with the emitter electrode toward the base layer.

Accordingly, when the emitter cap layer is formed thicker in order to increase the thickness of the base electrode, a spacing between the emitter layer and the base electrode also increases. Conversely, the emitter cap layer needs to be thinner in order to narrow the spacing between the emitter layer and the base electrode, but in this case, the base electrode is also thinned. In this way, in the related-art technology, the effect of reducing the base resistance is limited.

When all of the emitter cap layers can be removed by dry etching, a vertical sectional structure can be formed, and an undercut amount can be controllably minimized. However, when the dry etching is performed, plasma density or bias potential becomes locally nonuniform in the periphery of the emitter, which causes the in-plane distribution of the etching rate. There is also a concern that the formation of a plasma damaged layer on a surface of the emitter layer causes an effect such as degradation of current gain. In the dry etching, it is difficult to obtain sufficient etching selectivity between the emitter cap layer and the underlying emitter layer, so that it is very difficult to selectively and vertically remove only the emitter cap layer by the dry etching. In addition, it is very difficult to develop an InGaAs etchant having high selectivity with InP, hardly causing side etching, and having high verticality.

As described above, in the related art, there is a problem in that it is not easy to decrease the base resistance of the HBT to improve the high-frequency characteristics.

Embodiments of the present disclosure have been made to solve the above problems, and an object of embodiments of the present disclosure is to decrease the base resistance of the heterojunction bipolar transistor to improve the high-frequency characteristics.

### Means for Solving the Problem

According to one embodiment of the present disclosure, a heterojunction bipolar transistor includes: a collector layer formed over a substrate and made of a compound semiconductor; a base layer formed on the collector layer and made of a compound semiconductor; an emitter layer formed on the base layer, containing In and P, and made of a compound semiconductor different from the compound semiconductor of the base layer; an emitter cap layer formed on the emitter layer and made of a compound semiconductor containing In and As; a collector electrode connected to the collector layer; a base electrode formed on the base layer around the emitter layer; a first emitter electrode formed on the emitter cap layer, having an area greater than or equal to an area of the emitter cap layer in a plan view, and made of a tungsten alloy; a second emitter electrode formed on the first emitter electrode, made of a metal that contains tungsten and is different from a metal of the first emitter electrode, and having an area greater than the area of the first emitter electrode in a plan view; and a third emitter electrode formed on the second emitter electrode and made of a same type of metal as a metal of the base electrode.

According to another embodiment of the present disclosure, a heterojunction bipolar transistor manufacturing method includes: a first step of forming a collector forming layer made of a compound semiconductor over a substrate; a second step of forming a base forming layer made of a compound semiconductor on the collector forming layer; a third step of forming an emitter forming layer on the base forming layer, the emitter forming layer containing In and P and being made of a compound semiconductor different from the compound semiconductor of the base forming layer; a fourth step of forming an emitter cap forming layer made of a compound semiconductor containing In and As on the emitter forming layer; a fifth step of forming a first metal layer made of a tungsten alloy on the emitter cap forming layer; a sixth step of forming a second metal layer made of a tungsten alloy different from the tungsten alloy of the first metal layer on the first metal layer; a seventh step of patterning the second metal layer and the first metal layer to form a first emitter electrode formed on the emitter cap forming layer and a second emitter electrode formed on the first emitter electrode; an eighth step of patterning the emitter cap forming layer using the first emitter electrode as a mask to form an emitter cap layer on the emitter forming layer; a ninth step of patterning the emitter forming layer using the emitter cap layer as a mask to form an emitter layer on the base forming layer below the emitter cap layer; a tenth step of forming a third emitter electrode on the second emitter electrode and forming a base electrode on the base forming layer around the emitter layer; an eleventh step of patterning the base forming layer to form a base layer on the collector forming layer; a twelfth step of patterning the collector forming layer to form a collector layer; and a thirteenth step of forming a collector electrode. In the seventh step, the second emitter electrode is formed to have an area greater than an area of the first emitter electrode in a plan view, and in the eighth step, an oxide layer is formed by oxidation from a surface portion and removed, so that the emitter cap forming layer is patterned, and the emitter cap layer is formed.

As described above, according to embodiments of the present disclosure, the first emitter electrode having the area greater than or equal to the area of the emitter cap layer in a plan view is formed on the emitter cap layer, and the second emitter electrode having the area greater than the area of the first emitter electrode in a plan view is formed thereon, which can decrease the base resistance of the heterojunction bipolar transistor to improve the high-frequency characteristics.

### BRIEF DESCRIPTION OF THE DRAWINGS

FIG. 1 is a sectional view illustrating a configuration of a heterojunction bipolar transistor according to an embodiment of the present disclosure.

FIG. 2A is a sectional view illustrating a state of an element of an intermediate process for describing a method for manufacturing the heterojunction bipolar transistor according to an embodiment of the present disclosure.

FIG. 2B is a sectional view illustrating the state of the element of an intermediate process for describing the method for manufacturing the heterojunction bipolar transistor according to an embodiment of the present disclosure.

FIG. 2C is a sectional view illustrating the state of the element of an intermediate process for describing the method for manufacturing the heterojunction bipolar transistor according to an embodiment of the present disclosure.

FIG. 2D is a sectional view illustrating the state of the element of an intermediate process for describing the method for manufacturing the heterojunction bipolar transistor according to an embodiment of the present disclosure.

FIG. 2E is a sectional view illustrating the state of the element of an intermediate process for describing the method for manufacturing the heterojunction bipolar transistor according to an embodiment of the present disclosure.

FIG. 2F is a sectional view illustrating the state of the element of an intermediate process for describing the method for manufacturing the heterojunction bipolar transistor according to an embodiment of the present disclosure.

FIG. 2G is a sectional view illustrating the state of the element of an intermediate process for describing the method for manufacturing the heterojunction bipolar transistor according to an embodiment of the present disclosure.

FIG. 2H is a sectional view illustrating the state of the element of an intermediate process for describing the method for manufacturing the heterojunction bipolar transistor according to an embodiment of the present disclosure.

FIG. 3 is a sectional view illustrating a configuration of a heterojunction bipolar transistor.

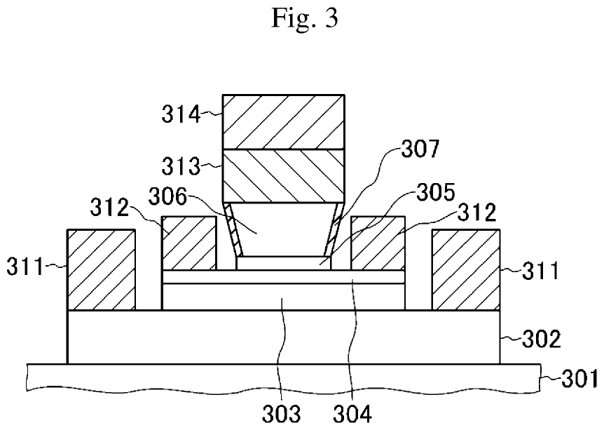

### DETAILED DESCRIPTION OF ILLUSTRATIVE EMBODIMENTS

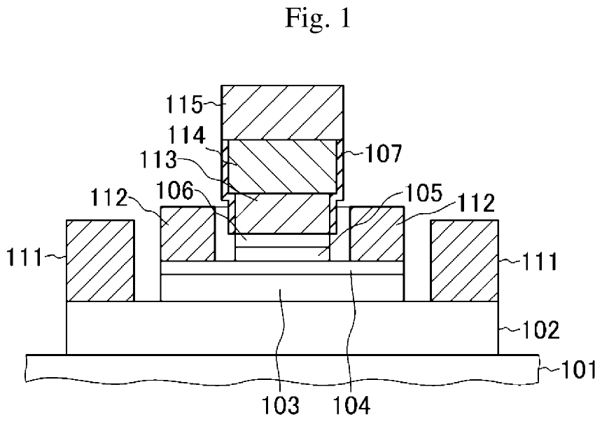

Hereinafter, a heterojunction bipolar transistor according to an embodiment of the present disclosure will be described with reference to FIG. 1.

The heterojunction bipolar transistor includes a collector layer 103 made of a compound semiconductor and formed over a substrate 101, a base layer 104 made of a compound semiconductor and formed on the collector layer 103, an emitter layer 105 formed on the base layer 104, containing In and P, and made of a compound semiconductor different from that of the base layer 104.

The heterojunction bipolar transistor includes an emitter cap layer 106 made of a compound semiconductor, containing In and As, and formed on the emitter layer 105. In the embodiment, the collector layer 103 is formed on a sub-collector layer 102 formed on the substrate 101.

A layered structure of the collector layer 103 and the base layer 104 forms a first mesa having a rectangular shape in a plan view, and a layered structure of the emitter layer 105 and the emitter cap layer 106 forms a second mesa having a rectangular shape in a plan view. The second mesa has an area smaller than the first mesa in a plan view.

For example, the substrate 101 is made of InP doped with Fe to have a high resistance. For example, the sub-collector layer 102 is made of InGaAs doped with an n-type impurity at a high concentration. The sub-collector layer 102 may have a two-layered structure including a layer made of InP proximate to the substrate 101 and a layer made of InGaAs and formed on the InP layer.

For example, the collector layer 103 is made of InP doped with an n-type impurity. The base layer 104 is made of p-type InGaAsSb doped with a p-type impurity at a high concentration. The emitter layer 105 is made of InGaP doped with an n-type impurity at a low concentration. InGaP is a compound semiconductor that contains In and P and is different from that of a base forming layer 204. The emitter cap layer 106 is made of InGaAs doped with an n-type impurity at a high concentration. InGaAs is a compound semiconductor containing In and

As.

The heterojunction bipolar transistor includes a collector electrode in electrically connected to the collector layer 103, a base electrode 112 formed on the base layer 104 around the emitter layer 105, and a first emitter electrode 113, a second emitter electrode 114, and a third emitter electrode 115 that are formed on or over the emitter cap layer 106.

The collector electrode 111 is formed on the sub-collector layer 102 around the collector layer 103 and electrically connected to the collector layer 103 through the sub-collector layer 102. The base electrode 112 is formed on the base layer 104 while surrounding an outer peripheral portion of the emitter layer 105 in order to decrease the base resistance.

The first emitter electrode 113 has an area greater than or equal to an area of the emitter cap layer 106 in a plan view, and is made of a tungsten alloy (for example, TiW). The first emitter electrode 113 is formed on the emitter cap layer 106. The second emitter electrode 114 is formed on the first emitter electrode 113, includes tungsten (W), is made of a different metal (for example, W) from that of the first emitter electrode 113, and has a larger area than that of the first emitter electrode 113 in a plan view. The third emitter electrode 115 is formed on the second emitter electrode 114 and is made of the same metal as that of the base electrode 112.

The first emitter electrode 113, which is formed to have a smaller area than that of the second emitter electrode 114 in a plan view, is disposed inside a region where the second emitter electrode 114 is formed. As a result, the outside of the region of the first emitter electrode 113 around the bottom surface of the second emitter electrode 114 serves as an overhang. When viewed from the direction of the second emitter electrode 114, the side face (side portion) of the first emitter electrode 113 is in a so-called undercut state. In a plan view, the first emitter electrode 113 has an area similar to or slightly larger than that of the emitter cap layer 106.

Furthermore, the heterojunction bipolar transistor of the embodiment includes a protective film 107 made of an insulating material and formed covering the side faces of the first emitter electrode 113 and the second emitter electrode 114. For example, the protective film 107 can be made of SiN, SiO₂, or Al₂O₃.

According to the embodiment described above, a thickness of the formable base electrode 112 can be controlled based on a thickness of the first emitter electrode 113, and a thickness of the emitter cap layer 106 can be freely designed. As a result, the emitter cap layer 106 can be thinned while the base electrode 112 is thickened by thickening the first emitter electrode 113.

Although the manufacturing method will be described below, a size of a shape of the emitter cap layer 106 in a plan view can be controlled with very high accuracy, and the spacing between the emitter and the base electrode can be precisely controlled. In this way, the resistance of the base electrode 112 can be decreased while the spacing between the emitter and the base electrode is accurately reduced, so that the base access resistance also can be decreased. Regarding the emitter cap layer 106, the dimensional accuracy of the shape in a plan view and the like can be controlled with very high accuracy, and the emitter can be precisely downsized.

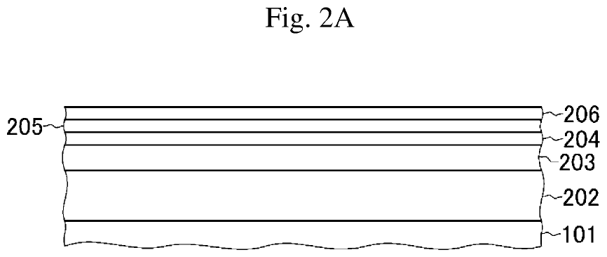

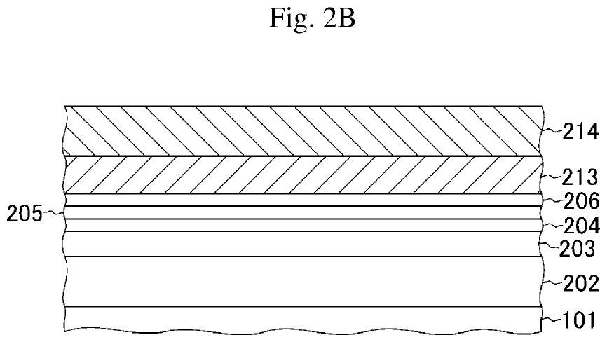

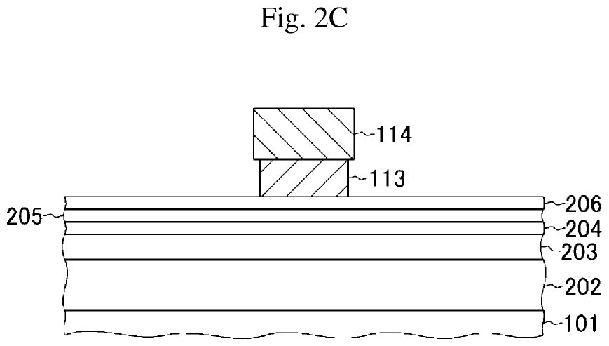

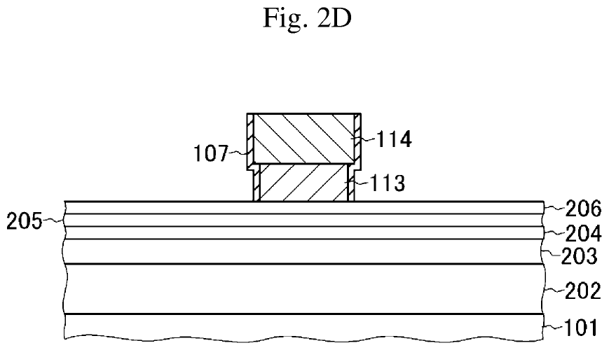

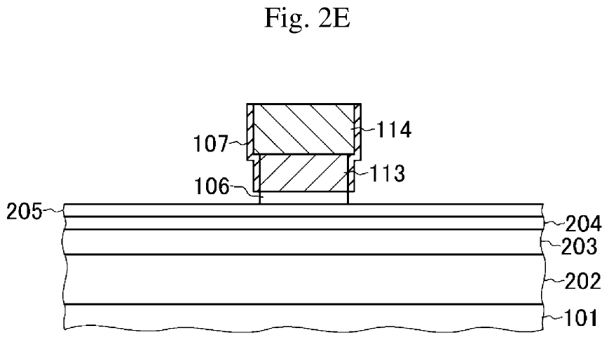

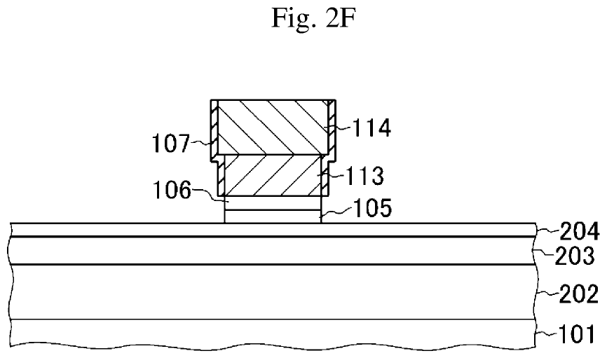

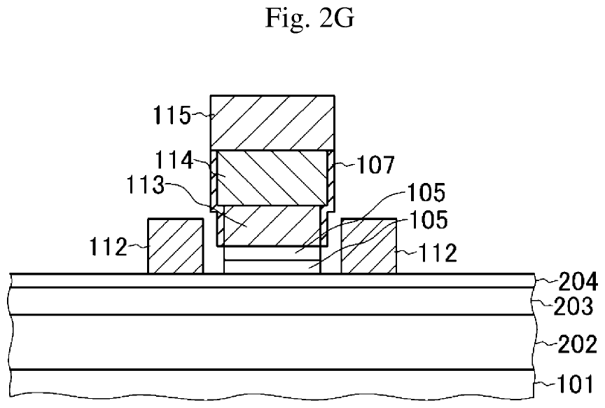

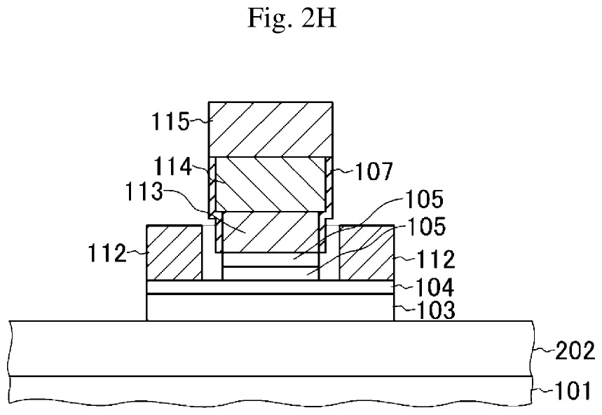

A method for manufacturing the heterojunction bipolar transistor according to an embodiment of the present disclosure will be described below with reference to FIGS. 2A to 2H. First, as illustrated in FIG. 2A, a sub-collector forming layer 202, a collector forming layer 203, a base forming layer 204, an emitter forming layer 205, and an emitter cap forming layer 206 are formed and layered in this order on or over the substrate 1o1 (a first step, a second step, a third step, and a fourth step).

For example, the sub-collector forming layer 202 is formed by crystal growth (epitaxial growth) of InGaAs doped with an n-type impurity at a high concentration. Subsequently, the collector forming layer 203 is formed by crystal growth of InP doped with an n-type impurity. Subsequently, the base forming layer 204 is formed by crystal growth of InGaAsSb doped with a p-type impurity at a high concentration. Subsequently, the emitter forming layer 205 is formed by crystal growth of InGaP doped with an n-type impurity at a low concentration. Subsequently, the emitter cap forming layer 206 is formed by crystal growth of InGaAs doped with an n-type impurity at a high concentration.

The thickness, the doping concentration, and the composition of each layer described above are set to optimal values, so that a desired electric performance is achieved. Because the thickness of the emitter cap forming layer 206 serving as the emitter cap layer 106 affects the spacing between the emitter and the base electrode, setting of this thickness requires attention. Specifically, the emitter cap forming layer 206 is desirably thinned as much as possible to minimize the spacing between the emitter and the base electrode. On the other hand, in terms of emitter contact resistance, when the emitter cap forming layer 206 is too thin, there is a concern that the emitter contact resistance increases. In consideration of both, the thickness of the emitter cap forming layer 206 is desirably about 10 nm to 50 nm. Each of the above-described layers can be formed by a well-known method such as organometallic vapor phase growing or molecular beam epitaxy.

Subsequently, as illustrated in FIG. 2B, a first metal layer 213 made of TiW is formed on the emitter cap forming layer 206 (fifth step), and a second metal layer 214 made of W is formed on the first metal layer 213 (sixth step). These can be formed using deposition techniques such as sputtering.

The first metal layer 213 and the second metal layer 214 may be made of any material as long as such a metal allows the areas of the first metal layer 213 and the second metal layer 214 to be formed smaller than the area of the second emitter electrode 114 when the later-described first emitter electrode 113 is formed. Specifically, various W alloys other than TiW, such as WN, WSi, and WSiN may be used.

The thickness of the base electrode 112 depends on the thickness of the first metal layer 213 that serves as the first emitter electrode 113 and the thickness of the emitter cap forming layer 206. For this reason, the thickness of the first metal layer 213 is made larger than a value obtained by subtracting the thickness of the emitter cap forming layer 206 from the thickness of the base electrode 112. Typically, sufficiently low base electrode resistance is obtained as long as the thickness of the base electrode 112 is approximately wo nm to 200 nm, so that the thickness of the first metal layer 213 can also be set to wo nm to 200 nm. As the thickness of the second metal layer 214, a thickness that is large enough to function as a mask in patterning the emitter cap forming layer 206 described later is selected.

Here, use of tungsten that is a high melting metal as the emitter electrode material can suppress electromigration and improve reliability particularly in the HBT required to perform a high current density operation.

Subsequently, the second metal layer 214 and the first metal layer 213 are patterned, the first emitter electrode 113 is formed on the emitter cap forming layer 206, and the second emitter electrode 114 is formed on the first emitter electrode 113 as illustrated in FIG. 2C (seventh step).

For example, a resist pattern is formed using a known lithography technique, the resist pattern is used as a mask, and the second metal layer 214 and the first metal layer 213 are etched by dry etching using a fluorine-based gas. In this etching process, the first metal layer 213 made of TiW is more likely to be etched in the surface direction of the substrate 101 than the second metal layer 214 made of W. Thus, the first emitter electrode 113 has a smaller dimension in the surface direction of the substrate 101 than that of the second emitter electrode 114 by the above-described etching process. By appropriately selecting etching conditions, the area of the first emitter electrode 113 in a plan view may be slightly smaller than the area of the second emitter electrode 114 in a plan view, so that the undercut structure is formed.

Subsequently, as illustrated in FIG. 2D, the protective film 107 made of the insulating material is formed covering the side faces of the first emitter electrode 113 and the second emitter electrode 114 (fourteenth step). For example, after the insulating material such as SiN, SiO₂, or Al₂O₃ is deposited to form the insulating film by known chemical vapor deposition, sputtering, or atomic layer deposition, and then etching back is performed by dry etching using a fluorine-based gas, whereby the protective film 107 can be formed.

In this manner, the formation of the protective film 107 can prevent the first emitter electrode 113 and the second emitter electrode 114 from being etched and changing in size in the process of forming the emitter cap layer 106. Also, the size of the shape of the emitter cap layer 106 in a plan view can be adjusted. The protective film 107 is desirably thinned in order to minimize the spacing between the emitter and the base electrode while the thickness is maintained to be large enough to function as an etching mask. The above effect can be sufficiently obtained when the thickness is about 5 nm to 50 nm.

Subsequently, as illustrated in FIG. 2E, the emitter cap layer 106 is formed on the emitter forming layer 205 by patterning the emitter cap forming layer 206 using the first emitter electrode 113 as a mask (eighth step). In forming the emitter cap layer 106, an oxide layer is formed by oxidation from a surface portion and removed, so that the emitter cap forming layer 206 is patterned. In this process, the first emitter electrode 113 is used as the mask, the emitter cap forming layer 206 is selectively oxidized from the surface portion, and the oxide layer formed by this oxidation is selectively removed by wet etching.

For example, immersion in a hydrogen peroxide-based solution (oxidation process) and a phosphoric acid-based etchant (etching process) enables formation of the above-described oxide layer and removal of the oxide layer. An extremely thin oxide layer having a subnanometer thickness is formed on the exposed surface of the emitter cap forming layer 206 in the oxidation process, and the extremely thin oxide layer is removed in the etching process. An etching amount can be precisely controlled by the number of iterations of the two processes rather than the immersion (treatment) time.

Thus, by appropriately setting the concentration of the solution and etchant used in the oxidation process and the immersion time, the emitter cap forming layer 206 can be etched and the emitter cap layer 106 can be formed with accuracy of sub-nanometer order without etching the first emitter electrode 113 and the second emitter electrode 114 (without impairing the emitter electrode shape).

In addition, in the above-described patterning process, a specific crystal surface of the compound semiconductor is not formed in the etching process, so that the shape equivalent to that of the etching mask (first emitter electrode 113) can be obtained in a plan view.

For example, when the wet etching is performed with a typical citric acid, the shape of the layer of InGaAs in a plan view becomes an octagonal shape composed of sides perpendicular to <0-1-1>, <0-10>, <0-11>, <001>, <011>, <010>, <010>, <01-1>, <00-1> directions or a hexagonal shape composed of sides perpendicular to <0-10>, <0-11>, <001>, <010>, <01-1>, <00-1> directions regardless of the shape of the etching mask, and the shape in a plan view is partially different from the shape of the etching mask.

The spacing between the emitter and the base electrode depends on the difference between the size of the shape of the emitter electrode in a plan view and the size of the shape of the emitter cap layer in a plan view. For this reason, related-art etching methods using citric acid have a difficulty in making the spacing between the emitter and the base electrode uniform over the entire periphery of the emitter. In contrast, according to the manufacturing method of the embodiment, the spacing between the emitter and the base electrode can be uniformly and precisely controlled.

In addition, in the patterning method in which the oxidation process and the etching process are alternately performed, the etching rate of the As-based compound is sufficiently faster than that of the P-based compound forming the emitter forming layer 205. Thus, the emitter cap layer 106 can be formed by selectively removing the emitter cap forming layer 206 with the emitter forming layer 205 hardly etched.

Subsequently, as illustrated in FIG. 2F, the emitter layer 105 is formed on the base forming layer 204 below the emitter cap layer 106 by patterning the emitter forming layer 205 using the emitter cap layer 106 as a mask (ninth step). For example, the emitter forming layer 205 is wet-etched with a known hydrochloric acid-based etchant using the emitter cap layer 106 as a mask, whereby the emitter layer 105 can be formed. As in the formation of the emitter cap layer 106, the emitter forming layer 205 can also be patterned, so that the emitter layer 105 is formed by a patterning method in which an oxidation process and an etching process are alternately performed.

Subsequently, as illustrated in FIG. 2G, the third emitter electrode 115 is formed on the second emitter electrode 114 and the base electrode 112 is formed on the base forming layer 204 around the emitter layer 105 (tenth step). For example, the electrode material is deposited by vacuum deposition after a resist pattern having an opening at each electrode forming location is formed by a known lithography. Then, the resist pattern is removed (lifted off), and the layer of the electrode material formed except in the electrode forming location is removed together with the resist pattern. Thus, the layer of the electrode material remains at the electrode forming location, and the third emitter electrode 115 and the base electrode 112 can be formed. In this case, the third emitter electrode 115 and the base electrode 112 are made of the same material (metal).

As described above, the thickness of the base electrode 112 may be designed to be smaller than the sum of the thicknesses of the first emitter electrode 113 and the emitter cap layer 106. In depositing the metal material that serves as the base electrode 112, the second emitter electrode 114 serves as an overhang, the third emitter electrode 115 and the base electrode 112 are separated, and the base electrode 112 can be formed near the emitter with no short-circuiting between the emitter and the base electrode 112.

Subsequently, the base forming layer 204 is patterned using a known lithography technique and a known etching technique, so that the base layer 104 is formed on the collector forming layer 203 as illustrated in FIG. 2H (eleventh step). The collector forming layer 203 is patterned, so that the collector layer 103 is formed (twelfth step). The collector electrode 111 is formed on the sub-collector forming layer 202 (thirteenth step). Thus, the heterojunction bipolar transistor in FIG. 1 is obtained.

Although the npn-type InP/GaAsSb-based HBT on the InP substrate that is promising in achieving the very-high-speed integrated circuit has been described in detail, other HBTs, specifically, an InP/InGaAs HBT and an InP-based HBT formed on an SiC heat dissipating substrate, also have the same effect.

As described above, according to embodiments of the present disclosure, the first emitter electrode having the area greater than or equal to the area of the emitter cap layer in a plan view is formed on the emitter cap layer, and the second emitter electrode having the area greater than the area of the first emitter electrode in a plan view is formed thereon, so that the emitter cap layer can be thinned while the base electrode can be thickened. As a result, embodiments of the present disclosure can decrease the base resistance of the heterojunction bipolar transistor to improve the high frequency characteristics.

Meanwhile, the present disclosure is not limited to the embodiments described above, and it will be obvious to those skilled in the art that various modifications and combinations can be implemented within the technical idea of the present disclosure.

Reference Signs List

| | | | |
|---|---|---|---|
| 101 | Substrate | 102 | Sub-collector layer |
| 103 | Collector layer | 104 | Base layer |
| 105 | Emitter layer | 106 | Emitter cap layer |
| 107 | Protective film | 111 | Collector electrode |
| 112 | Base electrode | 113 | First emitter electrode |
| 114 | Second emitter electrode | 115 | Third emitter electrode |
| 202 | Sub-collector forming layer | 203 | Collector forming layer |
| 204 | Base forming layer | 206 | Emitter cap forming layer |
| 213 | First metal layer | 214 | Second metal layer |

1-4. (canceled)

5. A heterojunction bipolar transistor comprising:
a collector layer on a substrate and comprising a first compound semiconductor;
a base layer on the collector layer and comprising a second compound semiconductor;
an emitter layer on the base layer and comprising a third compound semiconductor comprising In and P, wherein the third compound semiconductor is different from the second compound semiconductor of the base layer;
an emitter cap layer on the emitter layer and comprising a fourth compound semiconductor comprising In and As;
a collector electrode connected to the collector layer;
a base electrode on the base layer around the emitter layer;
a first emitter electrode comprising a tungsten alloy on the emitter cap layer, the first emitter electrode having an area greater than or equal to an area of the emitter cap layer in a plan view;
a second emitter electrode on the first emitter electrode, the second emitter electrode comprising tungsten and comprising a material different from the tungsten alloy of the first emitter electrode and having an area greater than the area of the first emitter electrode in the plan view; and
a third emitter electrode on the second emitter electrode and comprising a same type of metal as a metal of the base electrode.

6. The heterojunction bipolar transistor according to claim 5, further comprising a protective film comprising an insulating material and covering side faces of the first emitter electrode and the second emitter electrode.

7. The heterojunction bipolar transistor according to claim 5, wherein:
the first compound semiconductor comprises InP doped with a first n-type impurity;
the second compound semiconductor comprises p-type InGaAsSb doped with a p-type impurity;
the third compound semiconductor comprises InGaP doped with a second n-type impurity; and
the fourth compound semiconductor comprises InGaAs doped with a third n-type impurity.

8. The heterojunction bipolar transistor according to claim 5, wherein the first emitter electrode comprises TiW, WN, WSi, or WSiN.

9. A method of manufacturing a heterojunction bipolar transistor, the method comprising:
forming a collector forming layer comprising a first compound semiconductor on a substrate;
forming a base forming layer comprising a second compound semiconductor on the collector forming layer;
forming an emitter forming layer on the base forming layer, the emitter forming layer comprising In and P and comprising a third compound semiconductor different from the second compound semiconductor of the base forming layer;
forming an emitter cap forming layer comprising a fourth compound semiconductor comprising In and As on the emitter forming layer;
forming a first metal layer comprising a tungsten alloy on the emitter cap forming layer;
forming a second metal layer on the first metal layer, the second metal layer comprising tungsten and comprising a material different from the tungsten alloy of the first metal layer;
patterning the second metal layer and the first metal layer to form a first emitter electrode on the emitter cap forming layer and a second emitter electrode on the first emitter electrode, wherein the second emitter electrode has an area greater than an area of the first emitter electrode in a plan view;
patterning the emitter cap forming layer using the first emitter electrode as a mask to form an emitter cap layer on the emitter forming layer, wherein patterning the emitter cap forming layer comprises forming an oxide layer by oxidation from a surface portion and removing the oxide layer, so that the emitter cap forming layer is patterned and the emitter cap layer is formed;
patterning the emitter forming layer using the emitter cap layer as a mask to form an emitter layer on the base forming layer below the emitter cap layer;
forming a third emitter electrode on the second emitter electrode and forming a base electrode on the base forming layer around the emitter layer;
patterning the base forming layer to form a base layer on the collector forming layer;
patterning the collector forming layer to form a collector layer; and
forming a collector electrode.

10. The method according to claim 9, further comprising forming a protective film comprising an insulating material covering side faces of the first emitter electrode and the second emitter electrode.

11. The method according to claim 9, wherein:
the first compound semiconductor comprises InP doped with a first n-type impurity;
the second compound semiconductor comprises p-type InGaAsSb doped with a p-type impurity;
the third compound semiconductor comprises InGaP doped with a second n-type impurity; and
the fourth compound semiconductor comprises InGaAs doped with a third n-type impurity.

12. The method according to claim 9, wherein the first emitter electrode comprises TiW, WN, WSi, or WSiN.
